(19) United States
(12) Patent Application Publication
(10) Pub. No.: US 2020/0348339 A1
(43) Pub. Date: Nov. 5, 2020

(54) SUPPLEMENTARY BUSHING, TEST PROBE, AND SUPPLEMENTARY TESTING DEVICE

(71) Applicant: APEX PROBES TECHNOLOGY CO., LTD., ZHUBEI CITY (TW)

(72) Inventors: MING-DAO WU, ZHUBEI CITY (TW); SHIH-HUNG LO, ZHUBEI CITY (TW); HAO-WEN CHIEN, ZHUBEI CITY (TW); FU-CHENG CHUANG, ZHUBEI CITY (TW); WEI-CHU CHEN, ZHUBEI CITY (TW); KUO-WEI CHANG, ZHUBEI CITY (TW); BOR-CHEN TSAI, ZHUBEI CITY (TW); CHIH-FENG CHEN, ZHUBEI CITY (TW)

(21) Appl. No.: 16/398,294

(22) Filed: Apr. 30, 2019

(51) Int. Cl. G01R 1/067; G01R 1/16; G01R 1/073

(52) U.S. Cl. CPC G01R 1/06755; G01R 1/07314; G01R 1/16

(57) ABSTRACT

Disclosed are a supplementary bushing, a test probe, and a supplementary testing device. The supplementary bushing has a closed end, an open end, a receiving groove, and at least one first fixing portion. The closed end has a first contact, and the receiving groove is concavely formed from an open end towards the closed end. The first fixing portion is disposed on an inner surface of the receiving groove. The test probe is installed in the receiving hole of a base of the supplementary testing device and has a testing end and a connecting end. The testing end has a second contact, a second fixing portion and a stop portion.

### FIELD OF INVENTION

The present invention relates to the field of electrical testing devices, in particular to a test probe having a height arranged at the same level by using a supplementary method and an easy-to-maintain feature.

### BACKGROUND OF INVENTION

### 1. Description of the Related Art

In the present semiconductor industry, products such as IC chips must be tested by an electrical testing device installed with a probe to confirm the normal operation of the products. During the test, the probe is moved by a moving mechanism until the probe touches a contact of the chip and then the probe is returned to its original position. Since the friction produced by the probe touching the chip will wear out the front of the probe, therefore the length of the probe will be decreased by wearing after the test has been carried out for many times, and finally the length of the probe will be insufficient to touch the contact of the chip, and such probe loses its testing function.

When the above situation occurs, we simply replace the too-short probe with a new one. However, the size of the probe is very small, the structure is complicated, and the interval between every two pins is very narrow, so that it will take much time to remove and replace the probe, and the maintenance is inconvenient. Since the probe is worn out easily by the friction produced during the testing, only the front of the probe is provided for touching the contact of the test object, and other remaining portions still can be operated normally. For replacement, it is necessary to remove the whole probe and replace it with a brand new one, and thus increasing the maintenance cost of the testing device.

In view of the aforementioned issues, the inventor of the present invention based on years of experience in the related industry to conduct extensive research and experiment, and finally provided a supplementary bushing, a test probe, and a supplementary testing device to overcome the issues of high maintenance cost and long time required for the electrical testing and to provide a testing device with an easier use and a high maintenance speed.

### SUMMARY OF THE INVENTION

Therefore, it is a primary objective of the present invention to provide a supplementary bushing, a test probe and a supplementary testing device with the features of simple and easy maintenance of the electrical testing device and capable of preventing unnecessary wastes of usable structures, improving the maintenance efficiency, and shortening the required time.

To achieve the aforementioned and other objectives, the present invention discloses a supplementary bushing, provided to be sheathed on a test probe, comprising: a closed end, having a first contact, for forming a conduction with a test object; an open end, configured to be opposite to the closed end; a receiving groove, concavely formed from the open end towards the closed end; and at least one first fixing portion, disposed on an inner surface of the receiving groove, wherein the supplementary bushing is sheathed on a testing end of the test probe from the open end, and the first fixing portion and at least one second fixing portion of the testing end are configured relative to each other, and the testing end is disposed in the receiving groove. So that can ensure and maintain the accuracy of the test probe for electrical testing by using a substitution method.

In another embodiment, the present invention discloses a test probe provided to be installed in a receiving hole of a base, and the test probe has a testing end and a connecting end, and the connecting end is provided to be electrically coupled to a testing machine, and the testing end is configured to be opposite to the connecting end, characterized in that the testing end has a second contact, at least one second fixing portion and a stop portion, and the second contact is disposed at a terminal of the testing end, and the second fixing portion is disposed on an outer surface of the testing end, and the stop portion is disposed at an end of the second fixing portion, wherein the test probe is combined with the supplementary bushing, and the second fixing portion is corresponding to the first fixing portion, so that the testing end and the supplementary bushing are coupled with each other through the first fixing portion and the second fixing portion, and the stop portion is provided for stopping positioning, wherein the supplementary bushing is installed at a testing end, so that the test probe can continue a testing operation through a first contact of the test probe when a second contact of the test probe is worn out.

In a further embodiment, the present invention discloses a supplementary testing device, for performing an electrical or signal testing of a test object, comprising: a base, having a plurality of receiving holes; a plurality of test probes, installed in the receiving holes, and each of the test probes having a testing end and a connecting end configured to be opposite to each other, and the connecting end being provided to be electrically coupled to a testing machine, and the testing end protruding out from the receiving hole and having a second contact, at least one second fixing portion and a stop portion, and the second contact being disposed at a terminal of the testing end, and the second fixing portion being disposed on an outer surface of the testing end, and the stop portion being disposed at an end of the second fixing portion, and the testing end of each of the test probes protruding out from the receiving hole for a predetermined length, and the stop portions of the test probes on the base being disposed on a same level; and at least one supplementary bushing, having a closed end and an open end configured to be opposite to each other, a receiving groove concavely formed from the open end, and at least one first fixing portion disposed on an inner surface of the receiving groove, and the closed end having a first contact; wherein, when the second contact of any one of the test probes is worn out, the first fixing portion and the second fixing portion are coupled with each other until the supplementary bushing and the stop portion abut each other to stop the positioning, so that the length of the testing end of the test probe protruding out from the receiving hole resumes the predetermined length; wherein the supplementary bushing is installed at the testing end, so that the first contact can substitute the second contact to continue the testing operation if the second contact of the test probe is worn out and torn due to testing during the maintenance of the testing device. The invention not just accelerates the maintenance speed only, but also avoids the problems of having to remove the whole test probe, wasting components, and causing inconvenience.

In summation of the description above, the supplementary bushing, test probe and supplementary testing device of the present invention breaks through the conventional maintenance operation of the testing device, and avoids the inconvenience for removing and replacing the probe. With the concept of replacing the part in contact with the test object by the supplementary bushing, the maintenance operation consumes not much time, and avoids wasting the test probe (only the second contact is damaged). It is noteworthy that most test probes used for electrical testing are microstructures. In the conventional probe replacement operations, not just replacing the whole test probe with a new one only, but also disassembling the whole test probe to remove the components one by one, and then installing the components of the test probe into the receiving holes one by one. For the very small structure, it is very inconvenient to carry out the aforementioned replacement operation and will cause unnecessary waste. To reduce the level of difficulty and inconvenience of the maintenance operation, the assembled structure of the base and the test base is changed, or the structure of the test is changed directly. The test probe is a micro-structure, so that the redesign, manufacture, and assembling of the internal structure of the test probe incur a very high level of difficulty and also have a big problem for related manufactures. The supplementary bushing, test probe, and supplementary testing device in accordance with the present invention overcome the tremendous inconvenience effectively by adopting a simple assembling procedure, continuing the use of the worn or torn, and keeping the undamaged part of the test probe. When the supplementary bushing is worn, the worn-out supplementary bushing may be removed manually or mechanically, and then a brand new supplementary bushing 1 is installed in order to continue the use of the test probe.

### BRIEF DESCRIPTION OF THE DRAWINGS

FIG. 1 is a first schematic view of a supplementary testing device in accordance with a preferred embodiment of the present invention;

FIG. 2 is a second schematic view of a supplementary testing device in accordance with a preferred embodiment of the present invention;

FIG. 3 is a schematic view of a supplementary bushing and a test probe in accordance with a preferred embodiment of the present invention;

FIG. 4 is a schematic view of a supplementary bushing and a test probe in accordance with another preferred embodiment of the present invention; and

FIG. 5 is a schematic view of a supplementary bushing and a test probe in accordance with a further preferred embodiment of the present invention.

### DESCRIPTION OF THE PREFERRED EMBODIMENTS

To make it easier for our examiner to understand the objective, technical characteristics, structure, innovative features, and performance of the invention, we use preferred embodiments together with the attached drawings for the detailed description of the invention. It is noteworthy that the embodiments are provided for the purpose of illustrating the invention but not intended for limiting the scope of the invention.

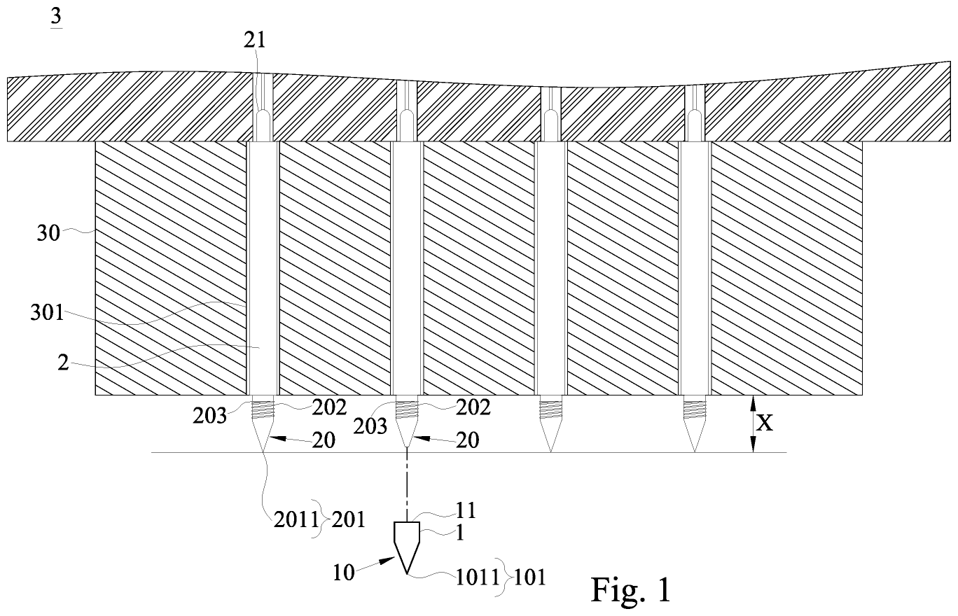

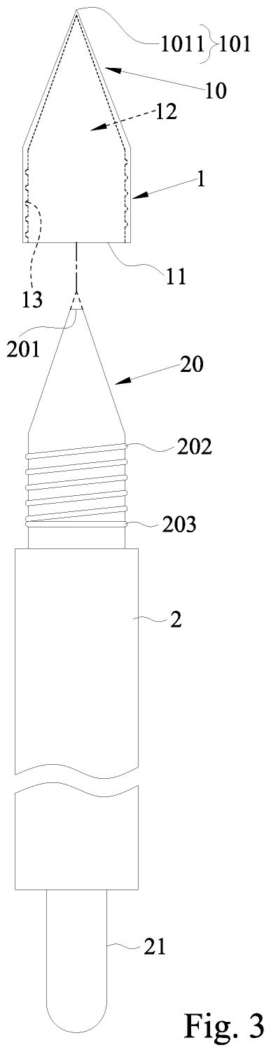

With reference to FIGS. 1 to 5, the inventor of the present invention overcomes the wear and tear problem of the test probe caused by the electrical testing by the design of substituting the damaged part without requiring too much disassembling and replacing efforts during a maintenance operation and providing a supplementary bushing 1 of the test probe, the test probe 2, and a supplementary testing device 3 having the supplementary bushing 1. The technical characteristics of the supplementary bushing 1, the test probe 2 and the supplementary testing device 3 are described in details as follows.

The supplementary bushing 1 comprises a closed end 10, an open end 11, a receiving groove 12 and at least one first fixing portion 13. The closed end 10 has a first contact 101 provided for touching a test object (not shown in the figure) to define a conduction. The open end 11 and the closed end 10 are configured to be opposite to each other. The receiving groove 12 is concavely formed from the open end 11 towards the closed end 10, and the first fixing portion 13 is disposed on an inner surface of the receiving groove 12, wherein the supplementary bushing 1 is sheathed on a testing end 20 of the test probe 2 from the open end 11, and the first fixing portion 13 and at least one second fixing portion 202 of the testing end 20 are configured to be relative to each other, and the testing end 20 is disposed in the receiving groove 12. When the test probe 2 is damaged, the supplementary bushing 1 has a substitution effect, so that it is not necessary to remove and replace the whole test probe 2. The invention lowers the product inspection and maintenance cost significantly. In an application, the supplementary bushing 1 may be installed before the use of the test probe 2 to extend the service life of the test probe 2. Preferably, the supplementary bushing 1 is a metal shell structure that can be sheathed on of the testing end 20 the test probe 2 to achieve the effect of substituting the testing end 20.

The test probe 2 connectable to the supplementary bushing 1 is installed in a receiving hole 301 of a base 30 and has a testing end 20 and a connecting end 21, and the connecting end 21 is provided to be electrically coupled to a testing machine (not shown in the figure), and the testing end 20 is configured to be opposite to the connecting end 21, characterized in that the testing end 20 further has a second contact 201, at least one second fixing portion 202 and a stop portion 203, and the second contact 201 is disposed at a terminal of the testing end 20, and the second fixing portion 202 is disposed on an outer surface of the testing end 20, and the stop portion 203 is disposed at an end of the second fixing portion 202, and the testing end 20 and the supplementary bushing 1 are coupled to each other through the first fixing portion 13 and the second fixing portion 202, and the stop portion 203 defines a stop of positioning. With the second fixing portion 202, the supplementary bushing 1 and the testing end 20 are coupled to each other, so that when the test probe 2 is damaged, a replacement for the maintenance and repair may be carried out through the supplementary bushing 1 without the need of discarding the whole test probe 2, and the length of the supplementary bushing 1 is preferably equal to the distance from the first contact 201 to the stop portion 203. Preferably, the test probe 2 is a Pogo Pin, a cantilever probe or a microelectromechanical (MEMs) test probe, but these test probes are prior arts and thus their structure will not be described in details. In addition, the stop portion 203 is a point or planar structure protruding from a surface of the testing end 20, so that when the supplementary bushing 1 is sheathed on the testing end, the supplementary bushing 1 will abut the stop portion to stop the positioning. Of course, the stop portion 203 may also be a concave structure, so that the first fixing portion can be latched to the stop portion 203 to define the stop of positioning.

Further, the supplementary testing device 3 of the present invention comprising a base 30, the plurality of test probes 2 and at least one supplementary bushing 1 is provide for carrying out an electrical or signal testing of a test object, wherein the base 30 has a plurality of receiving holes 301, and the test probes 2 are installed in the receiving holes 301 respectively, and each of the test probes 2 as described above has the testing end 20 and the connecting end 21 configured to be opposite to each other. When the test probes 2 are installed into the receiving holes 301, the testing end 20 of each of the test probes 2 protrudes with a predetermined length X out from the receiving hole 301, and the stop portions 203 of the test probes 2 on the base 30 are disposed at the same level, so that after the testing end 20 of any one of the test probes 2 is installed and coupled to the supplementary bushing 1, the testing end maintains at the same level of the testing end 20 of the other test probes 2. When the second contact 201 of any one of the test probes 2 is worn or torn, the supplementary bushing 1 is assembled and coupled through the first fixing portion 13 and the second fixing portion 202 until the supplementary bushing 1 abuts the stop portion 203, so that the length of testing end 20 of the test probe 2 protruding out from the receiving hole 301 resumes the predetermined length X to continue the testing operation. Even if the supplementary bushing 1 is damaged, the supplementary bushing 1 can be removed and replaced in order to continue the testing operation. Other structures of the test probes 2 can be used repeatedly to reduce the maintenance cost. If the second contact 201 of any one of the test probes 2 is worn or torn after the supplementary testing device 3 is used, and the length of the test probe 2 protruding out from the receiving hole 301 is smaller than the predetermined length X, then the supplementary bushing 1 will be sheathed on the testing end 20 of the test probe 2 in order to substitute the worn or torn second contact 201, and the second contact 201 will be used as a new contact for the test object to maintain the testing accuracy of the supplementary testing device 3.

In this embodiment, the first fixing portion 13 is an concave or convex threaded structure disposed around an inner surface of the receiving groove 12, and the second fixing portion 202 is a convex or concave threaded structure corresponding to that of the first fixing portion 13 and formed around the outer surface of the testing end 20, so that the supplementary bushing 1 and the test probe 2 can be assembled and fixed to each other by a screwing-in method or disassembled and separated by a screwing-out method through the connection of the first fixing portion 13 and the second fixing portion 202. Specifically, the supplementary bushing 1 may be screw into the testing end 20 or unscrewed from the testing end 20 manually or mechanically. In other words, if the length of the testing end 20 of any one of the test probes 2 protruding out from the receiving hole 301 is smaller than the predetermined length X, the supplementary bushing 1 is screwed and fixed into the second fixing portion 202 along a surface of the testing end 20 manually or mechanically until the supplementary bushing 1 is stopped by the stop portion 203, and the supplementary bushing 1 is screwed with a fixed length, so that the length of the test probe 2 installed with the supplementary bushing 1 and the length of other test probes 2 protruding out from the receiving holes 301 are all equal to the predetermined length X consistently. Wherein, the first fixing portion 13 is a concave threaded structure, and the second fixing portion 202 is a convex threaded structure, and the stop portion 203 is a thread end-point of the second fixing portion 202. Of course, the types of threads of the first fixing portion 13 and the second fixing portion 202 may be switched, and the stop portion 203 is a ring-shaped or arc-shaped bump structure protruding out from a surface of the testing end 20 in order to achieve the stop-positioning effect. The first fixing portion 13 and the second fixing portion 202 may be manufactured by a semiconductor manufacturing process, a laser manufacturing process, or a precision manufacturing method. When the second fixing portion 202 is a convex threaded structure, its external diameter is greater than the diameter of the testing end 20. When the second fixing portion 202 is a concave threaded structure, its external diameter is smaller than the diameter of the testing end 20. To ensure that the supplementary bushing 1 is fixed to the position of the stop portion 203 after the supplementary bushing 1 is sheathed on the test probe 2, all areas of the inner surface of the receiving groove 12 other than the first contact 101 are preferably the first fixing portion 13, and all areas of the testing end 20 other than the second contact 201 and the stop portion 203 are preferably the second fixing portion 202, and the first fixing portion 13 has a number of threads greater than the number of threads of the second fixing portion 202 to ensure that the supplementary bushing 1 is installed at the position of the stop portion 203, and the length and position of the supplementary bushing 1 sheathed on the test probe 2 are limited.

Further, an insulation layer of a surface of a test object may be pierced after the test probe 2 and the test probe 2 are installed to the supplementary bushing 1 for a testing, so that the first contact 101 and the second contact 201 have at least one point structure 1011, 2011, and the point structure 1011 of the first contact 101 has a height smaller than the height of the point structure 2011 of the second contact 201. In an embodiment, both of the first contact 101 and the second contact 201 have one point structure 1011, 2011, or the first contact 101 and the second contact 201 have a plurality of point structures 1011, 2011, and the point structures 1011, 2011 may be arranged in a divergent outward form, an inwardly aggregated form, or a vertically upward form to achieve the effect of piercing through the surface of the test object surface. In addition, the point structure 1011 of the first contact 101 has a height smaller than the height of the point structure 2011 of the second contact 201 to prevent the test probe 2 with the supplementary bushing 1 installed to the testing end 20 having a length protruding out from the receiving hole 301 unequal to those of other probes, due to the thickness of the supplementary bushing 1.

In addition, the extended length of the second fixing portion 202 is smaller than the length of the testing end 20 protruding out from the receiving hole 301 when the test probe 2 reaches its maximum stroke, and such arrangement prevents the test probe 2 from being affected by the second fixing portion 202 during the testing and leading to a reset failure or a jam.

It is noteworthy that the supplementary bushing 1 and the testing end 20 of the test probe 2 are designed to be magnetic in order to improve the installation and positioning strength of the test probe 2 and the supplementary bushing 1 and enhance the positioning effect of the test probe 2 and the supplementary bushing 1 by magnetic attraction, in addition to the connection of the first fixing portion 13 and the second fixing portion 202. In a preferred embodiment, both opposite sides (such as the left and right sides) of the supplementary bushing 1 have different magnetic poles, and the polarity of the testing end 20 and the polarity of the supplementary bushing 1 are configured to be corresponsive to each other, so that after the two are assembled and coupled, the magnetic poles are exactly opposite to one another, so that the heteropolar attraction of the assembled supplementary bushing 1 and test probe 2 improves the positioning and fixing effect significantly. Since the first fixing portion 13 and the second fixing portion 202 are structures with corresponding convex or concave threads, the threaded structures of the supplementary bushing 1 and the testing end 20 show an N or S-pole on one side and the opposite S or N-pole on the other side. After the supplementary bushing 1 and the testing end 20 are assembled and coupled to each other, a heteropolar attraction status is achieved. In other words, the N-pole position of the supplementary bushing 1 is configured to be corresponsive to the S-pole position of the testing end 20, and the S-pole position of the supplementary bushing 1 is configured to be corresponsive to the N-pole position of the testing end 20. As a result, the supplementary bushing 1 and the testing end 20 are attracted to each other. After the assembled and coupling relation between the supplementary bushing 1 and the test probe 2 is eliminated, the two may be separated.

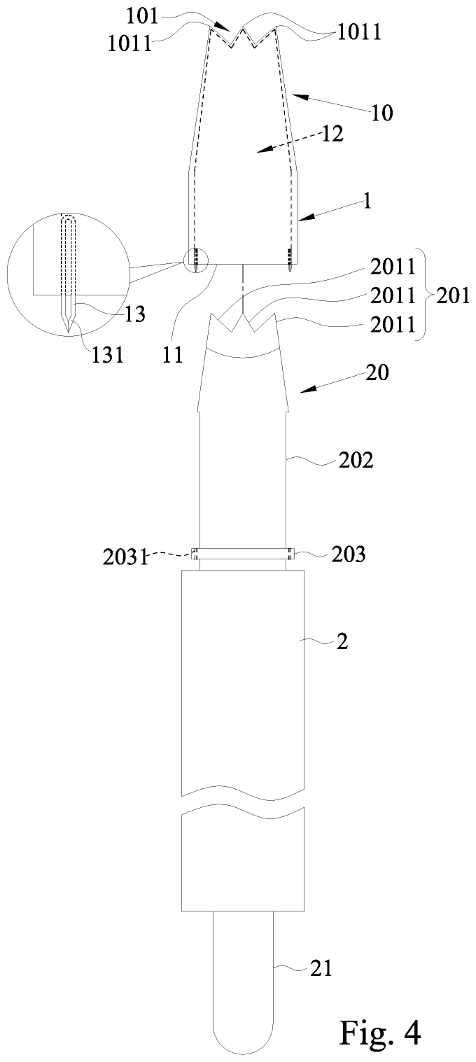

In FIG. 4, the first fixing portion 13 and the second fixing portion 202 are threaded structures. In this embodiment, the first fixing portion 13 is an elastic sheet and has a V-shaped bent structure 131, and the second fixing portion 202 is a sliding chute, and the stop portion 203 has at least one latch groove 2031. When the supplementary bushing 1 is sheathed on the testing end 20, the first fixing portion 13 is moved along the second fixing portion 202 until the V-shaped bent structure 131 is latched into the latch groove 2031. Therefore, when the supplementary bushing 1 is installed to the testing end 20, the first fixing portion 13 can slide along the second fixing portion 202, and then the V-shaped bent structure 131 can be latched into the latch groove 2031. In this embodiment, the supplementary bushing 1 has two first fixing portions 13, and the testing end 20 has two second fixing portions 202.

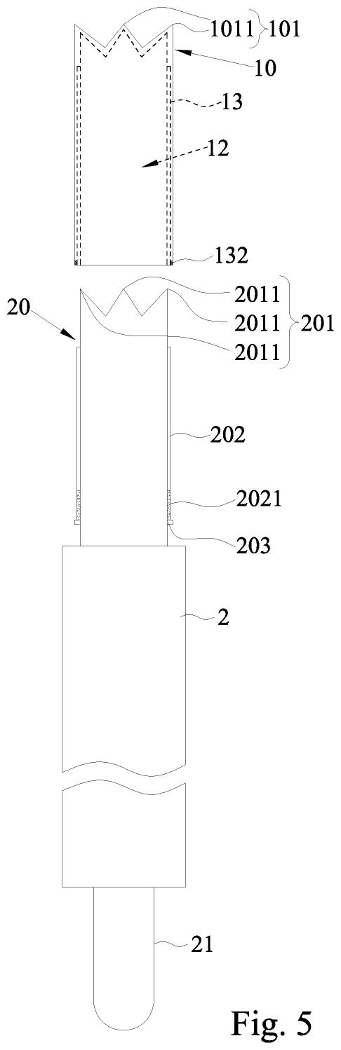

In addition to the aforementioned embodiments, the structure with the magnetic positioning and fixing function is described in details below. In the present invention, the first fixing portion 13 with a first magnetic part 132 and the second fixing portion 202 with a second magnetic part 2021 are coupled to each other, so that when the first fixing portion 13 and the second fixing portion 20 are fixed to each other and the first magnetic part 132 approaches or touches the second magnetic part 2021, the first magnetic part 132 has a first polarity, and the second magnetic part 2021 has a second polarity opposite to the first polarity, so that the first magnetic part 132 and the second magnetic part 2021 define a heteropolar attraction status, wherein the magnetic attraction between the first magnetic part 132 and the second magnetic part 2021 is greater than the weight of the supplementary bushing 1, so as to achieve the effect of keeping the supplementary bushing 1 at a position permanently. The weight mentioned here refers to the force caused by the weight of the supplementary bushing 1. For example, the first magnetic part 132 is a magnetically attracted substance such as iron, and the second magnetic part 2021 is a magnet with a N-pole and a S-pole. When the two approach or touch each other, the first magnetic part 132 under the effect of the second magnetic part 2021 changes its polarities to those opposite to the second magnetic part 2021 to achieve the heteropolar attraction effect. Of course, the effect will be the same, if the first magnetic part 132 is a magnet, and the second magnetic part 2021 is a magnetically attracted substance. If both of the first magnetic part 132 and the second magnetic part 2021 are magnets with the N-pole and S-pole, and the two are configured with at positions of different polarities, then the heteropolar attraction effect will be achieved. In the embodiment as shown in FIG. 5, the first fixing portion 13 is a sliding chute and has the first magnetic part 132, and the stop portion 203 is a rib, and the second fixing portion 202 is a bump, and when the supplementary bushing 1 is sheathed on the testing end 20, the second fixing portion 20 is moved along the first fixing portion 13, and the first magnetic part 132 and the second magnetic part 2021 are attracted and fixed to each other. When the supplementary bushing 1 and the test probe 2 are installed and coupled, the first fixing portion 13 and the second fixing portion 202 are provided to achieve the fixing and foolproof effects. The first magnetic part 132 and the second magnetic part 2021 are provided for a quick fixation to improve the speed of replacement.

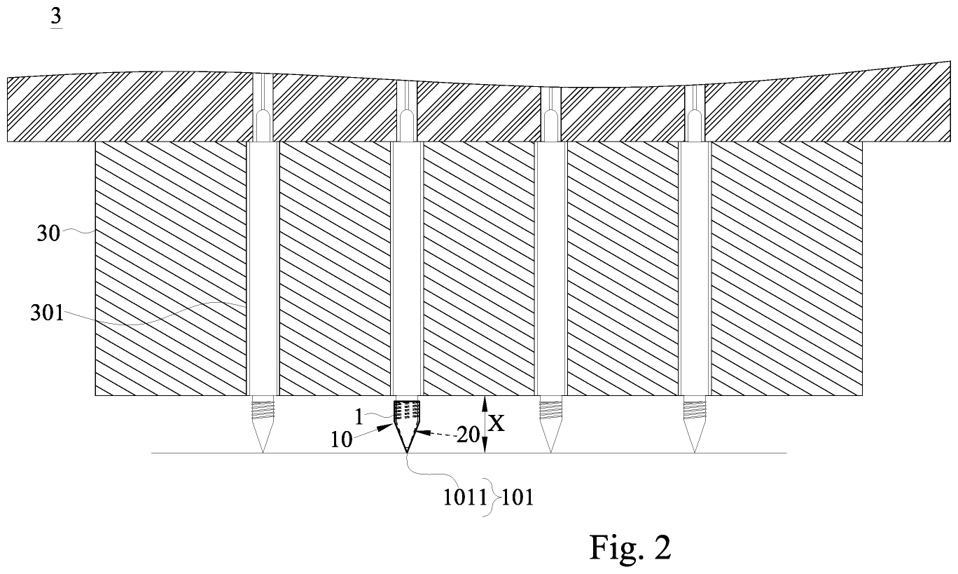

In an application as shown in FIGS. 1 and 2, after the test probes 2 are installed into the receiving holes 301 of the base 30, each of the test probes 2 protrudes with a predetermined length X out from each receiving hole 301. If a test object is tested and the second contact 201 of any one of the testing ends 20 is worn out, and the length of the test probe 2 protruding out from the receiving hole 301 is smaller than the predetermined length X, then the supplementary bushing 1 may be sheathed on the testing end 20, and the first contact 101 will substitute the second contact 201, and the length of this test probe 2 protruding out from the receiving hole 301 resumes the predetermined length X to maintain the other test probes 2 on the same level. Since each stop portion 203 is at the same level after the test probes 2 are installed into the receiving holes 301, therefore the supplementary bushing 1 sheathed onto the testing end 20 still stops at the same position to maintain the level of the test probes 2 even though the degree of worn-out of the second contact 201 is different. When the first contact 101 of the supplementary bushing 1 is worn out due to the testing, the supplementary bushing 1 is removed and then replaced by a new supplementary bushing 1 for the test probe 2. Therefore, the time and cost required for the maintenance operation can be reduced significantly, and the undamaged part of the second contact 201 of the test probe other still can be used, without the need of removing or replacing the whole test probe, so as to simplify the maintenance process for the probe replacement.

In summation of the description above, the supplementary bushing 1, test probe 2 and supplementary testing device 3 of the present invention breaks through the conventional maintenance operation of the testing device, and avoids the inconvenience for removing and replacing the probe. With the concept of replacing the part in contact with the test object by the supplementary bushing 1, the maintenance operation consumes not much time, and avoids wasting the test probe 2 (only the second contact 201 is damaged). It is noteworthy that most test probes used for electrical testing are microstructures. In the conventional probe replacement operations, not just replacing the whole test probe with a new one only, but also disassembling the whole test probe to remove the components one by one, and then installing the components of the test probe into the receiving holes one by one. For the very small structure, it is very inconvenient to carry out the aforementioned replacement operation and will cause unnecessary waste. To reduce the level of difficulty and inconvenience of the maintenance operation, the assembled structure of the base and the test base is changed, or the structure of the test is changed directly. The test probe is a micro-structure, so that the redesign, manufacture, and assembling of the internal structure of the test probe incur a very high level of difficulty and also have a big problem for related manufactures. The supplementary bushing 1, test probe 2, and supplementary testing device 3 in accordance with the present invention overcome the tremendous inconvenience effectively by adopting a simple assembling procedure, continuing the use of the worn or torn, and keeping the undamaged part of the test probe 2. When the supplementary bushing 1 is worn, the worn-out supplementary bushing 1 may be removed manually or mechanically, and then a brand new supplementary bushing 1 is installed in order to continue the use of the test probe 2.

What is claimed is:

1. A supplementary bushing, provided to be sheathed on a test probe, comprising:
a closed end, having a first contact, for forming a conduction with a test object;
an open end, configured to be opposite to the closed end;
a receiving groove, concavely formed from the open end towards the closed end; and
at least one first fixing portion, disposed on an inner surface of the receiving groove, wherein the supplementary bushing is sheathed on a testing end of the test probe from the open end, and the first fixing portion and at least one second fixing portion of the testing end are configured relative to each other, and the testing end is disposed in the receiving groove.

2. The supplementary bushing of claim 1, wherein the first fixing portion is an concave or convex threaded structure disposed around the inner surface of the receiving groove, and coupled to the second fixing portion which is a corresponding convex or concave threaded structure.

3. The supplementary bushing of claim 2, wherein the first fixing portion has a number of threads greater than the number of threads of the second fixing portion, and the first contact and a second contact of the testing end have at least one point structure, and the point structure of the first contact has a height smaller than the height of the point structure of the second contact.

4. The supplementary bushing of claim 1, wherein the first fixing portion is an elastic sheet and has a V-shaped bent structure, and an end protruding from a surface of the testing end and coupled to the second fixing portion with a stop portion having at least one latch groove, and when the supplementary bushing is sheathed on the testing end, the first fixing portion moves along the second fixing portion until a bent position of the first fixing portion is latched into the latch groove.

5. The supplementary bushing of claim 1, wherein the first fixing portion has a first magnetic part, coupled to the second fixing portion having a second magnetic part, and when the first fixing portion and the second fixing portion are coupled to each other and the first magnetic part approaches or touches the second magnetic part, the first magnetic part has a first polarity, and the second magnetic part has a second polarity opposite to the first polarity, and the first magnetic part and the second magnetic part form a heteropolar attraction status, and a magnetic attraction between the first magnetic part and the second magnetic part is greater than a weight of the supplementary bushing, so as to keep the supplementary bushing at a fixed position permanently.

6. The supplementary bushing of claim 5, wherein the first fixing portion is a sliding chute and has the first magnetic part, and an end protrude from a surface of the testing end, and coupled to the second fixing portion with a stop portion which is a rib, and when the supplementary bushing is sheathed on the testing end, the second fixing portion moves along the first fixing portion and is fixed by the mutual attraction between the first magnetic part and the second magnetic part.

7. A test probe, provided to be installed in a receiving hole of a base, and the test probe has a testing end and a connecting end, and the connecting end is provided to be electrically coupled to a testing machine, and the testing end is configured to be opposite to the connecting end, characterized in that the testing end has a second contact, at least one second fixing portion and a stop portion, and the second contact is disposed at a terminal of the testing end, and the second fixing portion is disposed on an outer surface of the testing end, and the stop portion is disposed at an end of the second fixing portion, wherein the test probe is combined with the supplementary bushing according to claim 1 and the second fixing portion is corresponding to the first fixing portion, so that the testing end and the supplementary bushing are coupled with each other through the first fixing portion and the second fixing portion, and the stop portion is provided for stopping positioning.

8. A supplementary testing device, for performing an electrical or signal testing of a test object, comprising:
a base, having a plurality of receiving holes;
a plurality of test probes, installed in the plurality of receiving holes, and each of the plurality of test probes having a testing end and a connecting end configured to be opposite to each other, and the connecting end being provided to be electrically coupled to a testing machine, and the testing end protruding out from the receiving hole and having a second contact, at least one second fixing portion and a stop portion, and the second contact being disposed at a terminal of the testing end, and the second fixing portion being disposed on an outer surface of the testing end, and the stop portion being disposed at an end of the second fixing portion, and the testing end of each of the plurality of test probes protruding out from the receiving hole for a predetermined length, and the stop portions of the plurality of test probes on the base being disposed on a same level; and
at least one supplementary bushing, having a closed end and an open end configured to be opposite to each other, a receiving groove concavely formed from the open end, and at least one first fixing portion disposed on an inner surface of the receiving groove, and the closed end having a first contact;
wherein, when the second contact of any one of the plurality of test probes is worn out, the first fixing portion and the second fixing portion are coupled with each other until the supplementary bushing and the stop portion abut each other to stop the positioning, so that the length of the testing end of the plurality of test probe protruding out from the receiving hole resumes the predetermined length.

9. The supplementary testing device of claim 8, wherein the first fixing portion is an concave or outward convex threaded structure, and the second fixing portion is an convex or concave threaded structure corresponding to the first fixing portion.

10. The supplementary testing device of claim 9, wherein the first fixing portion has a number of threads greater than the number of threads of the second fixing portion, and the first contact and the second contact have at least one point structure, and the point structure of the first contact has a height smaller than the height of the point structure of the second contact, and an extended length of the second fixing portion is smaller than an extended length of the testing end protruding out from the receiving hole when the plurality of test probe reaches a maximum stroke.

11. The supplementary testing device of claim 8, wherein the first fixing portion is an elastic sheet and has a V-shaped bent structure, and the second fixing portion is a sliding chute, and the stop portion has at least one latch groove, and when the supplementary bushing is sheathed on the testing end, the first fixing portion moves along the second fixing portion until the V-shaped bent structure is latched into the latch groove.

12. The supplementary testing device of claim 8, wherein the first fixing portion has a first magnetic part, and the second fixing portion has a second magnetic part, and when the first fixing portion and the second fixing portion are coupled with each other and the first magnetic part approaches or touches the second magnetic part, the first magnetic part has a first polarity, and the second magnetic part has a second polarity opposite to the first polarity, so that the first magnetic part and the second magnetic part form a heteropolar attraction status, wherein a magnetic attraction between the first magnetic part and the second magnetic part is greater than a weight of the supplementary bushing to achieve the effect of keeping the supplementary bushing at a fixed position permanently.

13. The supplementary testing device of claim 12, wherein the first fixing portion is a sliding chute and has the first magnetic part, and the stop portion is a rib, and the second fixing portion is a bump, and when the supplementary bushing is sheathed on the testing end, the second fixing portion moves along the first fixing portion and is fixed by the mutual attraction between the first magnetic part and the second magnetic part.
